(19) United States
(12) Patent Application Publication
(10) Pub. No.: US 2026/0264889 A1
(43) Pub. Date: Sep. 10, 2026

(54) DEVICE AND METHOD FOR MANUFACTURING SOLID FUEL MICROTHRUSTERS USING ONLY PCB-MEMS TECHNOLOGY

(71) Applicant: UNIVERSIDAD DE SEVILLA, Sevilla (ES)

(72) Inventor: Jose Manuel QUERO REBOUL, Sevilla (ES)

(21) Appl. No.: 19/118,439

(22) PCT Filed: Oct. 3, 2023
(86) PCT No.: PCT/ES2023/070586

§ 371 Date: Apr. 4, 2025

(30) Foreign Application Priority Data
Oct. 4, 2022 (ES) P202230853

(51) Int. Cl. B64G 1/40; B64G 1/26; B81B 7/04; B81C 1/00; H05K 1/02; H05K 1/14; H05K 3/00

(52) U.S. Cl. CPC B64G 1/403; B64G 1/26; B64G 1/4021; B81B 7/04; B81C 1/00047; H05K 1/0272; H05K 1/144; H05K 3/0044; B81B 2201/038; B81B 2203/0315; B81B 2203/033; B81B 2203/0384; H05K 2201/042; H05K 2201/09036; H05K 2201/09063; H05K 2201/09827

(57) ABSTRACT

Microthruster applicable in space engineering comprising PCB boards joined together, wherein the first board comprises a fuel tank and an outlet nozzle and the second board is provided with a detonator, the tank containing a solid explosive fuel, wherein the microthruster is characterized in that it is manufactured only using PCB-MEMS technology. The use of PCB-MEMS technology allows for a high scale of integration, high operational reliability and lower manufacturing costs.

### OBJECT OF THE INVENTION

This device and its manufacturing method are applicable in space engineering, to apply forces and/or moments to satellite platforms. The device behaves like an array of micro rockets that use solid fuel. Each of these devices has a controlled trigger, allowing the attitude and/or orbit of the artificial satellite on which it is mounted to be modified. The use of PCB-MEMS technology allows for a high scale of integration, high operational reliability and lower manufacturing costs. The device belongs to the micropropulsion technology and the field of microelectromechanical microsystems (MEMS).

### STATE OF THE PRIOR ART

Micropropulsion system is the key subsystem of most micro spacecraft and is mainly used for position maintenance, attitude control and orbit adjustment of space platforms such as microsatellites, nanosatellites and picosatellites, as well as for satellite end-of-life propulsion to ensure satellite disintegration in the atmosphere (de-orbiting). A micropropulsion system based on MEMS technology has the advantages of miniaturization, integration and low power consumption. Therefore, it has become an important alternative for manufacturing micropropulsion systems.

There are different physical principles for propulsion in space [1]. Among them, the most notable are electrical and chemical technologies for use in micro and nano satellites such as CUBESAT. In turn, among the chemical technologies, the most notable are cold gas, monothrusters, bithrusters, solid fuel thrusters, hybrid thrusters, water electrolysis, etc. Solid fuel thrusters are the simplest, since they do not require tanks or valves, although they are the ones with the lowest performance.

Solid-state microthrusters use an array arrangement of small microthrusters, which are triggered individually to achieve discrete micropulses. The combination of several simultaneous triggers allows a range of total discrete pulses to be obtained depending on the propulsion needs.

There are numerous works whose manufacturing is based on MEMS technology. In CN109774976A [2] the manufacture of an array of thrusters in silicon is proposed. Its structure is standard, including a tank with solid fuel, a detonator and a nozzle made of silicon. On the one hand, it is necessary to highlight the complexity of its manufacturing, and on the other, that its manufacturing process requires that the nozzle outlets of these devices be made perpendicular to the manufacturing plane, occupying a lot of space on the surface of the satellite.

In CN108757361A [3] the manufacturing of a MEMS microthruster similar to the previous one is proposed, including a tank with solid fuel, a detonator and a nozzle made of silicon, with the same limitations as the previous patent.

Other relevant examples of MEMS-based thrusters include those defined in [4][5] and a review of the use of MEMS technology for the manufacture of microthrusters can be found in [6]. All these systems have a common structure of tank, detonator and nozzle. In addition, they are manufactured using silicon as the base material and its associated MEMS manufacturing techniques. The use of MEMS technologies in silicon penalizes its manufacture by making it expensive, slow and also requiring highly specialized machinery. Another disadvantage of using silicon as a substrate is that it is a good thermal conductor, which causes the problem that when a thruster is triggered, other adjacent thrusters are activated [7]. Another drawback is the difficulty of connecting all the detonators to the electronic triggering system, given the electrical connection limitations of MEMS technology in silicon. Finally, the fact that the nozzle exits of these devices are perpendicular to the manufacturing plane takes up a lot of space on the satellite surface, to the detriment of their use for solar panels, solar sensors or observation instruments.

This patent develops a method for manufacturing an array of microthrusters using exclusively Printed Circuit Board (PCB) technology, solving the previous technical problems, making its use acceptable since it is a mature technology widely used in the satellite sector.

### DESCRIPTION OF THE INVENTION

The method described below allows the manufacture of micro thrusters for satellites with solid fuel using exclusively PCB technology. The tank (1) and the outlet nozzle (2) of the microthruster are made on a printed circuit board 1 (FIG. 1), carving the FR4 substrate and maintaining the outer copper layer on both sides. The detonator (6) is manufactured on a printed circuit board 2 (FIG. 2) using a copper track as a resistor. The tank (1) is filled with solid fuel. The plates are joined either by welding or by adhesive, applying pressure and temperature between them. To prevent the adhesive or flux from penetrating the tank or nozzle, trenches can be used around the perimeter (5). Optionally, holes can be added to introduce guides to facilitate alignment during the joining process of the two plates. When current passes through the detonator, it reaches a temperature higher than the ignition temperature of the fuel, activating the propulsion. The nozzle outlet of the microthruster is arranged on the edge of the PCB board, minimizing the surface exposed to the outside of the satellite. To facilitate joining the plates by welding, blind tracks (3) are used to transfer heat between the plates. Additionally, hollow tracks (6) are used to be able to use an aligner during the joining of the plates. Both welded plates are shown in FIG. 3.

The described method allows the manufacture of 2D arrays of microthrusters, as shown in FIG. 4, at very low cost and using very simple machinery. The use of PCB technology, which has been well developed and known for decades, provides versatility in the design of these microthrusters and high reliability to the product. The use of multilayer PCB facilitates the interconnection of the microthruster array.

These microthrusters can be connected in series, allowing sequential triggering with gas output through a common nozzle, as shown in FIG. 5, wherein the external microthruster (8) would be triggered first and then the internal one (9) would be triggered.

A connector (7) can be integrated into one of the plates to allow electrical connection of the detonator to the outside of the microthruster.

These 2D microthruster arrays can be stacked to create a 3D microthruster structure to increase the thrust capability of the device, as shown in FIG. 6.

Using PCBMEMS technology, the device can be manufactured using a mature and accessible technology, wherein the carving of both the FR4 substrate and the copper layers is common. The ability to manufacture tracks on multilayer PCBs multiplies the possibilities of wiring the microthrusters. The use of FR4 material reduces thermal propagation, avoiding the triggering of adjacent microthrusters. The use of a single technology facilitates the integration of the different elements of the microthruster.

### DESCRIPTION OF FIGURES

FIG. 1: Plate 1 containing on its upper side a) the tank and the nozzle and a ring to protect against tin overflow during welding. Two holes are used to facilitate alignment during the welding process. On the lower side there is a layer of copper. Tracks between the two sides facilitate heat transmission between them.

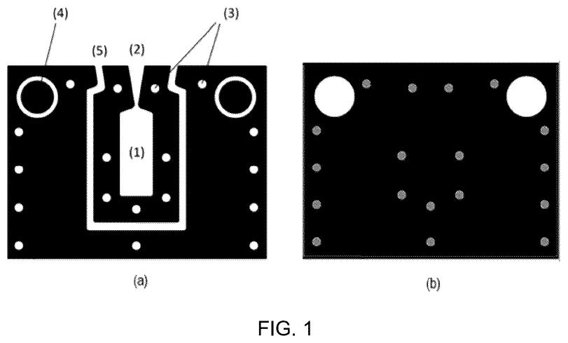

FIG. 2: Plate 2 with the detonator on its upper surface.

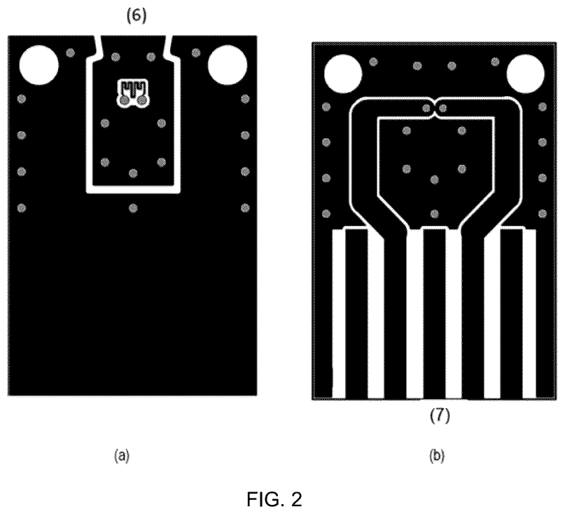

FIG. 3: Section of a microthruster with the two plates joined together.

FIG. 4: Array (parallel) arrangement of microthrusters.

FIG. 5: Design with two microthrusters in series.

FIG. 6: Section of an example of stacking three 2D arrays of microthrusters to obtain a 3D structure.

### DESCRIPTION OF A PREFERRED EMBODIMENT OF THE INVENTION

The method described below allows the manufacture of micro thrusters for solid-fuel satellites using exclusively PCB technology.

It is based on the design of the plate 1 containing the solid fuel tank (1) and the nozzle (2), which are made by machining both the copper surface sheet and the FR4 substrate. The dimensions of the tank are calculated in such a way that the width and depth of the nozzle determine the microthruster pulse, while the length determines the pulse duration. The nozzle is designed using conventional convergent/divergent nozzle techniques. The rest of the copper surface sheet is left intact to facilitate subsequent welding. Blind tracks filled with copper (3) are included to promote heat transfer from one copper face to the other. In addition, a trench (5) is added to prevent tin or adhesive from overflowing and falling into the tank or nozzle during the bonding process.

The detonator (6) is manufactured on a printed circuit board 2 using a copper track as a resistor. The section of this track must be small enough to ensure that the temperature reached when a current is passed through is sufficient to activate the solid fuel. The rest of the board is left covered in copper to facilitate subsequent welding. Additionally, holes (4) can be included to introduce guides that facilitate alignment during the bonding process.

Additionally, matching and through holes (4) can be included in plate 1 and plate 2 to facilitate their alignment by introducing a guide into said holes.

The faces to be joined on plate 1 and 2 are tinned.

The tank (1) is then filled with black powder, which is used as solid fuel.

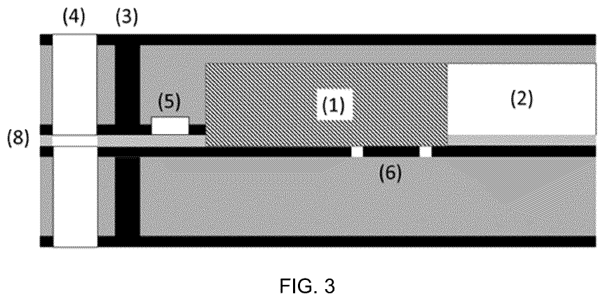

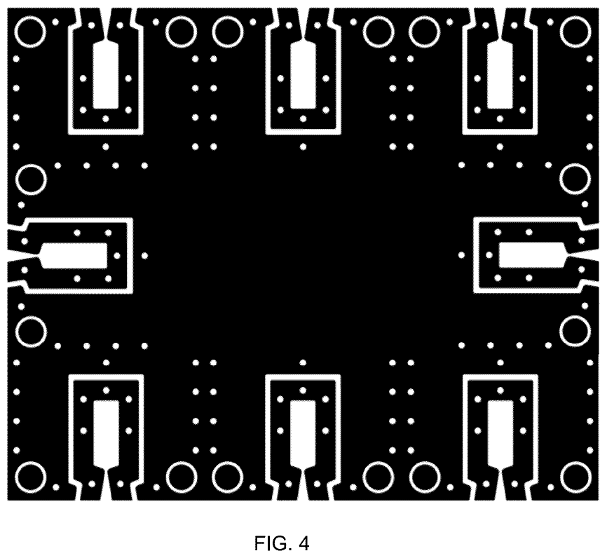

The plates are joined by welding by applying pressure and temperature between them, typically 100 Kg/cm2 and 220° C. respectively. As a result, both plates are welded together as shown in the section in FIG. 3. The temperature for welding the plates must be higher than the melting point of tin, which is about 250° C., but lower than the combustion temperature of black powder (solid fuel), which is about 500° C. The final welded assembly is shown in FIG. 4.

In this case there is a connector (7) built into plate 2 to facilitate the connection of the microthruster detonator to a generator that provides the triggering current. This current must be high enough so that, due to the Joule effect of the detonator resistance (6), it generates the heat necessary to exceed the ignition temperature of the black powder.

The method described above allows the manufacturing of 2D arrays of microthruster as shown in FIG. 4, simply by replicating the microthrusters on the outline of a PCB board and working in parallel. The different detonators would be connected by tracks to a connector to independently give them their trigger current.

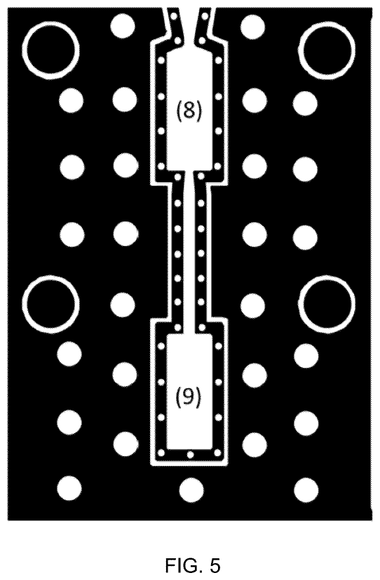

These microthrusters can be connected in series, allowing sequential triggering with gas output through a common nozzle, as shown in FIG. 5, wherein the external microthruster (7) would be triggered first and then the internal one (8).

The combination of this array arrangement together with the ability to connect thrusters in series manages to maximize the number of microthrusters integrated into a 2D structure.

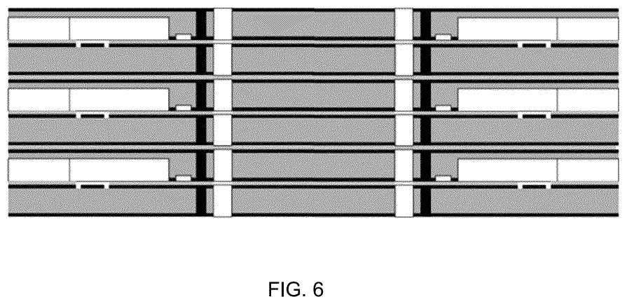

These 2D microthruster arrays can be stacked to create a 3D microthruster structure to increase the number of integrated devices. FIG. 6 shows as an example the superposition of three 2D arrays to create a 3D structure.

By using only PCBMEMS technology, the device can be manufactured using a mature and accessible technology, taking advantage of its properties: a) chemical etching of the copper layers and mechanical milling of the substrate are common processes in this technology, reaching accuracies of tens of microns; b) the ability to manufacture multilayer PCB tracks multiplies the wiring possibilities of the microthrusters; c) the use of FR4 material reduces thermal propagation, avoiding the trigger of adjacent microthrusters; d) The use of these 2D structures minimizes the outer surface of the nozzles for gas evacuation, leaving the outer surface of the satellite for other uses; e) the flexibility of this technology allows the microthrusters to be arranged in array and series, as well as their simultaneous triggering, to meet the operating requirements of the satellite.

The claims are amended as follows:

1. Microthruster comprising a first and second PCB boards joined together, wherein the first board comprises a fuel tank and an outlet nozzle made by machining and the second board is provided with a detonator also machined, the tank containing a solid explosive fuel that is activated by the detonator so that during ignition of the fuel, the gases produced exit through the nozzle creating an impulse, wherein the microthruster is characterized in that it is manufactured only using PCB MEMS technology.

2. Microthruster according to claim 1, the two plates of which are welded together by means of tin or bonded together by means of adhesive.

3. Microthruster according to claim 1 that includes trenches on the faces to be welded to prevent molten tin or adhesive from entering the tank and the nozzle.

4. Microthruster according to claim 1 that has matching through holes on the two plates that allow them to be aligned by means of through guides during the bonding process.

5. Microthruster according to claim 1, whose detonator is made with a conductor track or a conductor wire that, when a current passes through it, exceeds the ignition temperature of the solid fuel.

6. 2D device with multiple microthrusters according to claim 1, wherein the microthrusters adopt an arrangement with outputs on the edge of the structure and which are triggered independently.

7. 2D device with multiple microthrusters according to claim 1 adopting a series arrangement, wherein the outlet of an inner thruster expels the gases to the tank of an outer microthruster, and wherein multiple microthrusters share a common outlet nozzle.

8. 3D device formed by multiple 2D structures according to claim 6.

9. Manufacturing method of a microthruster according to claim 1, characterized by the steps of:
machining on a first PCB board a fuel tank (1) and an outlet nozzle (2);
machining on a second PCB board a detonator (6);
introduction of a solid fuel into the tank;
joining the first and second boards by tin welding or bonding with adhesive, wherein the microthruster is manufactured only using PCB MEMS technology.
